(19) United States
(12) Patent Application Publication
(10) Pub. No.: US 2023/0223944 A1
(43) Pub. Date: Jul. 13, 2023

(54) PHASE NOISE PERFORMANCE USING MULTIPLE RESONATORS WITH VARYING QUALITY FACTORS AND FREQUENCIES

(71) Applicant: Skyworks Solutions, Inc., Irvine, CA (US)

(72) Inventors: Aslamali A. Rafi, Austin, TX (US); Srisai Rao Seethamraju, Nashua, NH (US)

(21) Appl. No.: 18/080,630

(22) Filed: Dec. 13, 2022

Related U.S. Application Data
(63) Continuation of application No. 17/354,089, filed on Jun. 22, 2021, now abandoned.

(51) Int. Cl. H03L 7/099; H03L 7/23; H03B 5/32; H03L 7/093

(52) U.S. Cl. CPC H03L 7/0992; H03L 7/235; H03B 5/326; H03L 7/093

(57) ABSTRACT

Nested phase-locked loops (PLLs) utilize resonators of different quality factors, oscillation frequencies, and tunability. A reference clock signal for a first PLL is based on a free running bulk acoustic wave (BAW) resonator. The first PLL utilizes an LC oscillator as a voltage controlled oscillator. A crystal oscillator supplies a reference clock signal to a second PLL. Feedback dividers of the first and second PLLs are coupled to the LC oscillator. A delta sigma modulator coupled to the loop filter of the second PLL controls the feedback divider of the first PLL. The first PLL utilizes a high update rate to ensure that the jitter power spectral density is spread over a wide frequency range. The nested PLL architecture allows the overall phase noise plot to follow that of the crystal resonator at low frequencies, the BAW resonator at mid-frequencies, and the LC resonator at high frequencies.

Any and all applications for which a domestic priority claim is identified in the Application Data Sheet of the present application are hereby incorporated by reference under 37 CFR 1.57.

### BACKGROUND

### Field of the Invention

This disclosure relates to clock products and more particularly to reducing jitter in clock products.

### Description of the Related Art

The high data rates used in current wired-line and wireless communication systems require the use of clock sources with very low jitter. Clock sources often utilize phase-locked loops to provide clock signals required by modern communication systems. FIG. 1 illustrates a high level block diagram of a typical clock source 100. A typical clock source 100 includes a phase-locked loop (PLL) 101 with a phase-frequency detector (PFD) 103, a loop filter 105, a voltage controlled oscillator (VCO) 107 and a feedback divider 109. A crystal oscillator 111 supplies the reference clock signal 115 to the PFD 103. The PFD 103 compares the reference clock signal to the feedback signal 117 and supplies an error signal indicative of the phase difference between the signals. That difference is used by the loop filter 105 to control the frequency of VCO 107. The divider 109 determines the frequency of the output signal 119. The VCO 107 may be implemented using an LC oscillator, a bulk acoustic wave resonator, or another tunable oscillator. As explained further herein, using a bulk acoustic wave resonator as the tunable oscillator has disadvantages. The clock source 100 can have drawbacks in terms of jitter associated with various components in the PLL and from various sources.

FIG. 2 illustrates a block diagram of another clock product—a conventional voltage controlled crystal oscillator (VCXO) 200. The conventional VCXO includes the PLL 101 and an analog to digital converter (ADC) 201 that converts the control voltage signal 203 to a digital signal that is supplied to the delta sigma modulator (DSM) 205. The DSM controls the feedback divider 109 to adjust the output frequency of the VCO according to the control voltage. In the conventional VCXO illustrated, a divider 207 divides the output of the VCO and a buffer 209 drives the desired signal. The VCXO 200 can suffer from the same drawbacks in terms of jitter associated with various components in the VCXO and from various sources.

While many techniques have been used to lower jitter in timing products, it would be desirable to provide additional ways to reduce jitter in timing products.

### SUMMARY OF EMBODIMENTS OF THE INVENTION

Accordingly, in one embodiment an apparatus includes a bulk acoustic wave (BAW) resonator to supply a BAW signal. A first phase-locked loop (PLL) includes a first phase frequency detector (PFD) coupled to a first reference clock signal, which is based on the BAW signal. The first phase detector supplies a first error signal that indicates a difference between a first feedback signal and the first reference clock signal. A first feedback divider supplies the first feedback signal to the first PFD. A first loop filter is coupled to the first phase detector and supplies a first loop filter output signal that is based on the first error signal. An LC oscillator is coupled to the first loop filter output signal and supplies an LC oscillator signal. The LC oscillator output signal is coupled to the first feedback divider. A crystal oscillator supplies a crystal oscillator signal. A second PLL includes a second PFD that receives a second reference clock signal that is based on the crystal oscillator signal and the second PFD supplies a second error signal that indicates a difference between the second reference clock signal and a second feedback signal. A second feedback divider is coupled to the LC oscillator signal and supplies the second feedback signal to the second PFD. A second loop filter is coupled to the second PFD and supplies a second loop filter output signal based on the second error signal. A first divider control circuit is coupled to the second loop filter output signal to control the first feedback divider.

In another embodiment a method includes supplying a bulk acoustic wave (BAW) signal from a BAW resonator. A first phase frequency detector (PFD) of the first PLL receives a first reference clock signal based on the BAW signal and supplies a first error signal from the first PFD. The first error signal is based on a first difference between the first reference clock signal and a first feedback signal. A loop filter generates a first loop filter output signal to control an LC oscillator of the first PLL based on the first error signal. The LC oscillator supplies an LC oscillator signal. A first feedback divider circuit generates the first feedback signal in based in part, on the LC oscillator signal. A crystal oscillator generates a crystal oscillator signal. A second PFD of a second PLL receives a second reference clock signal based on the crystal oscillator signal and supplies a second error signal indicative of a difference between the second reference clock signal and a second feedback signal. A second feedback divider generates the second feedback signal based in part on the LC oscillator signal. The second PFD supplies a second error signal to a second loop filter. The second error signal is based on a second phase difference between the second reference clock signal and the second feedback signal. The second loop filter generates a second loop filter output signal based on the second error signal. The second loop filter output signal is received at a first delta sigma modulator and the first delta sigma modulator controls a first divide value of the first feedback divider.

In another embodiment an apparatus includes a plurality of nested phase-locked loops (PLLs). A bulk acoustic wave (BAW) or surface acoustic wave (SAW) resonator is coupled to a first PLL of the nested PLLs. A crystal oscillator is coupled to a second PLL of the nested PLLs. A first feedback divider of the first PLL and a second feedback divider of the second PLL are coupled to an LC oscillator of the first PLL. A first delta sigma modulator is coupled to a loop filter of the second PLL to control the first feedback divider. An update rate of the first PLL is at least an order of magnitude greater than a frequency of the crystal oscillator.

### BRIEF DESCRIPTION OF THE DRAWINGS

The present invention may be better understood, and its numerous objects, features, and advantages made apparent to those skilled in the art by referencing the accompanying drawings.

FIG. 1 is a high level block diagram of a conventional clock source.

FIG. 2 is a high level block diagram of a conventional voltage controlled crystal oscillator (VCXO).

FIG. 3 shows in tabular form the quality factor (Q), the oscillation frequency, the tunability, and size of several resonators.

FIG. 4 illustrates an embodiment of nested PLLs.

FIG. 5 is a graph of jitter power spectral density (PSD) of three resonators.

FIG. 6 illustrates a nested loop implementation of a VCXO.

FIG. 7 illustrates a triple nested loop.

The use of the same reference symbols in different drawings indicates similar or identical items.

### DETAILED DESCRIPTION

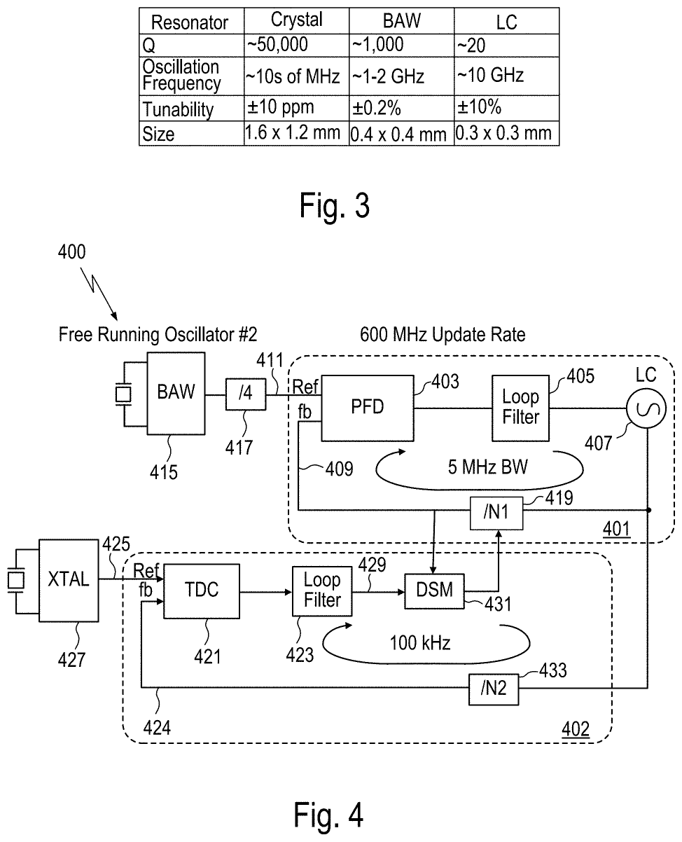

Timing product systems have options as to the type of resonators to use. Resonators are available that have different quality factors, sizes, frequencies of oscillation, tunability, and price. FIG. 3 shows in tabular form the quality factor (Q), the oscillation frequency, the tunability, and size of several resonators available today. The quartz based resonator used in crystal oscillators has a very high Q (˜50,000), has an oscillation frequency in the tens of MHz, is not very tunable, and is relatively large. A piezo-electric resonator such as a bulk acoustic wave (BAW) resonator has a lower Q (˜1000), a high oscillator frequency (˜2 GHz), and is more tunable that a quartz resonator. A BAW resonator is typically formed of a piezoelectric material (e.g., aluminum nitride (AlN)) sandwiched between two electrodes. A surface acoustic wave resonator can also be used as the piezo-electric resonator. Finally, an LC based oscillator has a low Q (˜20), a high oscillation frequency (˜10 GHz), and is very tunable. In terms of cost, the LC resonator is cheapest, followed by the BAW, and finally the quartz resonator, which is relatively expensive compared to the other two resonators.

Embodiments herein exploit beneficial qualities associated with each type of resonator shown in FIG. 3 to provide a nested PLL system that uses different kinds of resonators. FIG. 4 illustrates an embodiment of nested PLLs 400. The nested PLLs 400 includes PLL 401 (inner loop) and PLL 402 (outer loop). The PLL 401 includes a phase-frequency detector (PFD) 403, a loop filter 405, and a VCO implemented as an LC oscillator 407. The PFD 403 receives a feedback signal 409 and a reference clock signal 411 and generates an error signal that is supplied to the loop filter 405. The loop filter controls the LC oscillator 407 based on the error signal. The feedback divider 419 is coupled to the LC oscillator directly, or through a divider, and generates the feedback signal 409. The reference clock signal 411 is based on the output of the bulk acoustic wave (BAW) resonator 415. A divider 417 divides the BAW output signal to generate the reference clock signal 411. In an embodiment, the divider 417 divides the BAW resonator output signal so that the reference clock signal has a frequency of approximately 600 MHz providing an approximately 600 MHz update rate for the PLL 401. The update rate for the PLL determines how often PLL values such as the PFD output are updated and depend in part on the reference clock frequency. A high update rate allows the PLL to be adjusted more frequently than a PLL with a low update rate.

The PLL 402 (the outer loop) controls the divider 419 of the inner loop. The PLL 402 includes the time to digital converter (TDC) (more generally a PFD) 421 that supplies an error signal to the loop filter 423. The error signal reflects the difference between the feedback signal 424 and the reference clock signal 425. The crystal oscillator 427 supplies the reference clock signal 425. The loop filter uses the error signal from PFD 421 to generate a control signal 429 for delta sigma modulator (DSM) 431. DSM 431 functions as a divider control circuit to control the N1 feedback divider 419 of the inner loop, where N1 represents the divider value for the feedback divider 419. The feedback divider 433 is coupled to the LC oscillator 407 and generates the feedback signal 424, where N2 represents the divider value for the feedback divider 433. Thus, the LC oscillator is utilized by the outer loop 402 as well as the inner loop 401. The outer loop typically has a smaller bandwidth than the immediately inner loop and the innermost loop has the widest bandwidth and the outermost loop has the narrowest bandwidth. In embodiments, the narrow bandwidth PLLs are implemented using digital architectures because the large time-constants needed to realize the low bandwidths can be implemented as weights in the digital domain whereas such narrow bandwidth PLLs would require very large chip area to implement the loop filter capacitor in the analog domain. The use of the TDC in FIG. 4 recognizes the advantages of a digital implementation for PLL 402.

In an embodiment, the loop bandwidth of the inner loop (PLL 401) is 5 MHz but more generally is between 1 and 10 MHz. In an embodiment, the loop bandwidth of the outer loop (PLL 402) is 100 kHz, but more generally is between 10 kHz and 500 kHz. The loop bandwidth of the inner loop should be at least an order of magnitude greater than the loop bandwidth of the outer loop to ensure that the inner loop can filter noise associated with the outer loop.

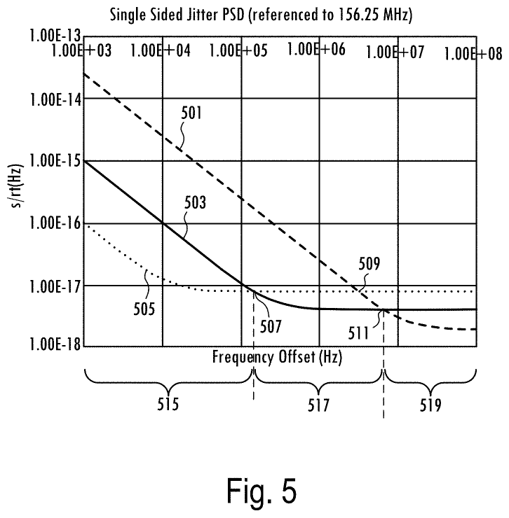

The choice of resonators for the nested PLLs can be better understood by looking at the jitter power spectral density (PSD) shown in FIG. 5. The Y axis shows seconds/square root (Hz) and the X axis shows frequency offset. The jitter PSD shown in FIG. 5 is referenced to 156.25 MHz, which is a typical frequency of interest in telecommunication systems. Curve 501 shows the single sided jitter PSD for the LC oscillator. Curve 503 shows the single sided jitter PSD for the BAW resonator. Curve 505 shows the single sided jitter PSD for the crystal oscillator. Note that while the sloping regions of the jitter density curves are independent of frequency of operation, the flat portion of the jitter power spectral density is inversely proportional to the frequency of operation of the resonator, that is the oscillation frequency. In other words, high frequency oscillators have a lower jitter density floor. On the other hand, the sloping part of jitter density plot is only a function of the quality factor of the resonator. The jitter associated with the flat portion of curves is associated with the squaring function to convert a sinusoid supplied by the reference frequency oscillators to a square wave in a manner well known in the art. As shown in FIG. 5, the crystal resonator has the highest Q and the lowest jitter PSD for the sloping part of the curve. FIG. 5 shows that given the variation in quality factors and frequency of operation between the three resonators, the jitter density profiles intersect at 507, 509, and 511.

Referring to FIGS. 4 and 5, PLL 401 uses the LC oscillator as the VCO and the BAW resonator as the reference clock signal (through divider 417). The overall phase noise performance is improved by using the crystal resonator in the nested PLL circuit along with the BAW resonator and LC oscillator. The nested PLLs 400 allow the overall phase noise plot to follow that of the crystal resonator at low frequencies (shown as region 515), the BAW resonator at mid-frequencies (shown as region 517), and the LC resonator at high frequencies (shown as region 519).

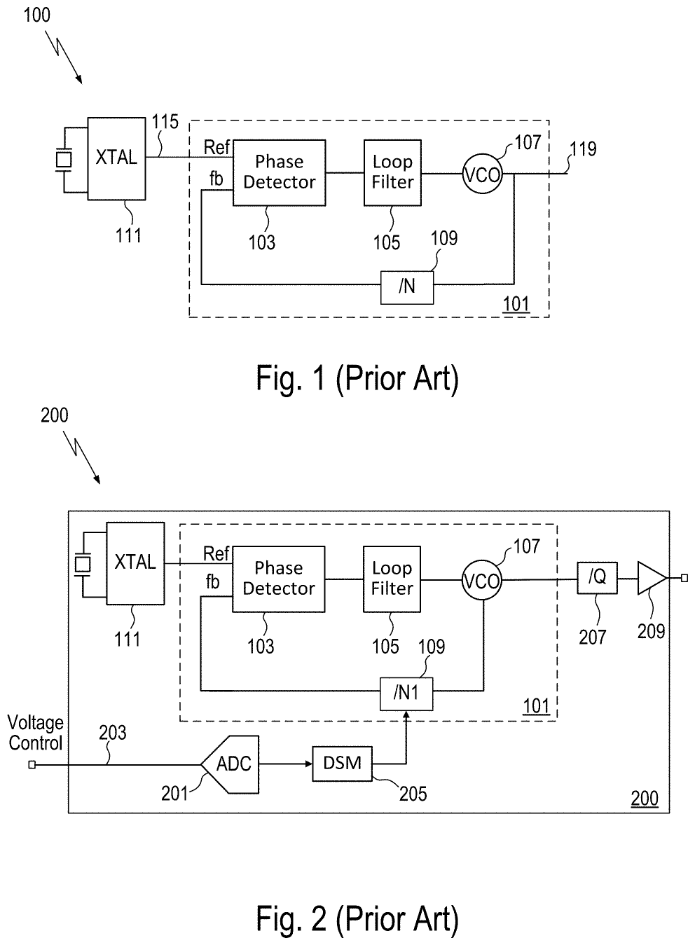

Furthermore, while it is possible to use the BAW as a VCO as described in relation to FIG. 1, such use can degrade the phase noise performance of the BAW resonator. That is because the VCO, by definition, needs a frequency control port and the range of frequency control needs to be adequate to cover the inherent frequency drift of the resonator with temperature. Note that the BAW resonator is sensitive to temperature, e.g., 25-30 ppm/degree C. Frequency control in a VCO is typically achieved through switching capacitors across the resonator and thereby changing its frequency. But given the high frequency of operation, the switched capacitors are of finite quality and degrade the effective quality factor of the high Q BAW resonator. Degraded noise performance would result from the use of the BAW resonator in the VCO instead of the LC oscillator.

The nested PLL architecture shown in FIG. 4 avoids using the BAW as a VCO and thereby prevents phase noise degradation. The nested PLLs 400 uses a lower Q but highly tunable LC oscillator as a VCO to achieve any-rate frequency generation capability. That is, the LC oscillator can be tuned to a wide range of frequencies, e.g., from MHz to GHz. The nested PLL architecture uses an ultra-high Q crystal resonator as a reference for PLL 402 and thereby benefits from the good frequency stability of the crystal and low frequency phase noise performance while avoiding its thermal noise floor (the flat region shown in FIG. 5). The use of the BAW resonator as the reference for PLL 401 effectively limits the frequency range over which the crystal resonator's phase noise is dominant. That allows the use of a crystal resonator with a much worse noise floor without impacting the RMS jitter significantly. In other words, the architecture of FIG. 4 uses each resonator in its most advantageous phase noise region, while avoiding the use of high Q oscillators as VCOs. Since the BAW resonator can have process variations in terms of its oscillation frequency, those variations are readily addressed by the nested loop architecture. That can help achieve a lower cost system. Note that the single sided jitter PSD was referenced to 156.25 MHz in FIG. 5. If the jitter PSD was referenced to a higher frequency, e.g., 600 MHz, which is the update rate of the embodiment shown in FIG. 4, the noise floor would be ˜6 dB lower than shown in FIG. 5.

Referring back to FIG. 4, the three resonators are used in the nested circuit 400. The inner loop 401 utilizes a free running BAW resonator (or a SAW resonator) as the reference source, which thereby avoids capacitive tuning. That results in better phase noise performance as described earlier. The inner loop 401 is clocked at a relatively high frequency (in the embodiment illustrated in FIG. 4, ˜600 MHz) because the BAW has a high frequency as compared to, e.g., a crystal oscillator. The relatively high update rate lowers the jitter power spectral density as it is spread over a wider frequency range (as compared to say 100 MHz), resulting in a lower phase noise floor. Preferably, the update rate of the inner loop is at least an order of magnitude higher than the oscillation frequency of the crystal oscillator. As described earlier, the BAW resonator is temperature sensitive. As the temperature drifts and the frequency of the BAW resonator changes, that change is compensated by the action of the outer loop (PLL 402) which is clocked by the crystal resonator. The bandwidths of the inner loop is made high (e.g., 5-10 MHz or in the range described earlier, while the bandwidth of the outer loop is kept small, e.g., 100 kHz or in the range described earlier. Ultimately, the bandwidths are chosen as a function of the phase noise performance of the individual resonators. Finally, the VCO in the nested PLL configuration is designed out of a lower-Q but highly tunable LC oscillator. That achieves any-rate frequency flexibility while delivering excellent phase noise performance and lower cost.

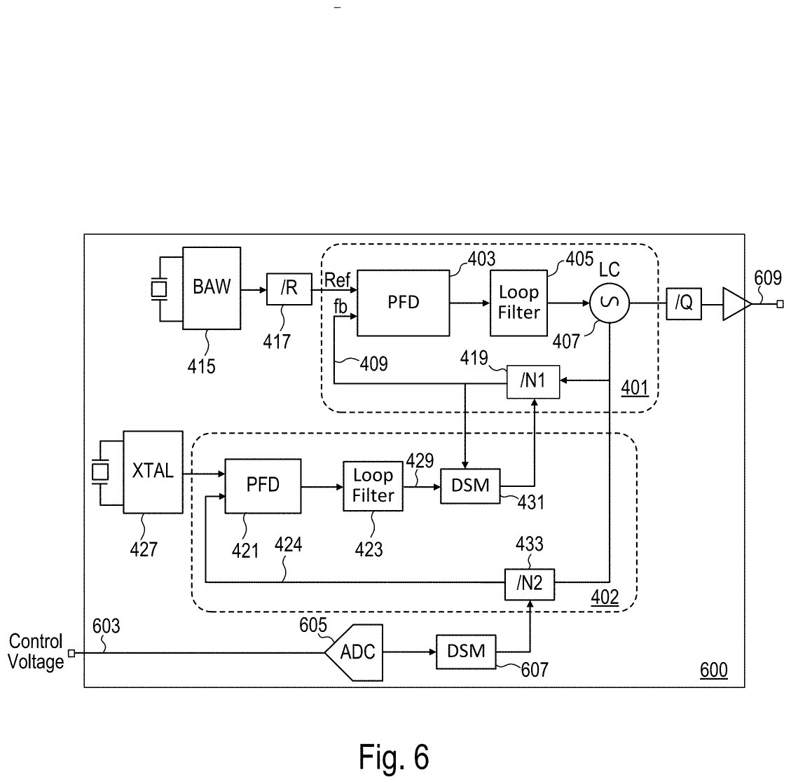

FIG. 6 illustrates a nested loop implementation of a VCXO. Referring again to FIG. 2, the traditional VCXO product shown in FIG. 2 includes only two resonators: a crystal oscillator and an LC oscillator. That results in undesirable phase noise associated with the traditional VCXO product. Referring to FIG. 6, the inclusion of a third resonator with a different frequency and Q in the VCXO 600, results in a better phase noise profile. The inner loop 401 and the outer loop 402 of VCXO 600 are similar to those in FIG. 4. In addition, VCXO 600 receives a control voltage signal 603 that is received by the ADC 605. The ADC 605 supplies a digital signal to the DSM 607 that corresponds to the control voltage signal and DSM 607 supplies divide values to the feedback divider 433 of outer loop 402. In that way the control voltage signal controls the output 609 of the VCXO 600. As was the case with the nested PLLs of FIG. 4, it is possible to use a cheaper and lower frequency crystal for the reference clock signal for the outer loop 402 as the phase noise of the crystal oscillator is filtered by the inner loop containing the higher frequency resonator. Note that the inner and outer loops in the various embodiments described herein can be analog or digital or any appropriate combination of analog and digital logic.

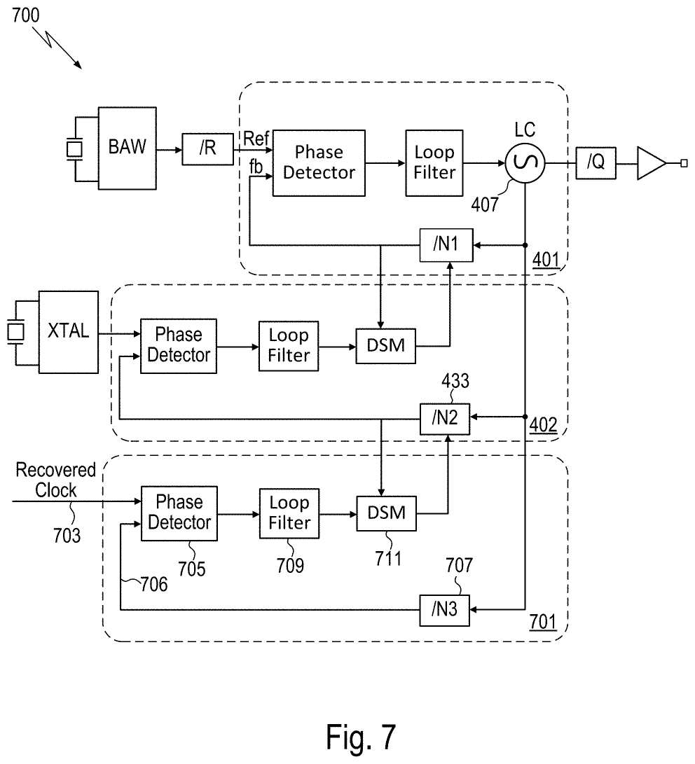

While the nested loop architecture using various resonators with different frequencies and quality factors can be used in a VCXO, such as architecture can be advantageously used in other timing products. For example, referring to FIG. 7, a triple nested loop 700 has a phase noise profile that is improved by the use of the three resonators: the crystal, BAW, and LC. The first two PLLs 401 and 402 are the same as those shown in FIGS. 4 and 6. The nested loop 700 includes a third PLL 701. The third PLL 701 receives a recovered clock 703. A clock and data recovery (CDR) circuit (not shown in FIG. 7), which is well known in the art, recovers the clock signal from data received by the CDR and supplies the recovered clock signal 703. The phase detector 705 receives the recovered clock signal 703, compares the recovered clock signal 703 to the feedback signal 706 from feedback divider 707, and supplies an error signal indicative of the comparison. The loop filter 709 receives the error signal and supplies a loop filter output to the DSM 711, which controls the divider 433 in PLL 402. The divider 433 is now the middle loop. In that way the output from the LC 407 is locked to the recovered clock signal. Because the recovered clock signal is a noisy signal, the bandwidth of the PLL 701 is narrow to filter out the noise. For example in an embodiment the bandwidth of the PLL 701 is at least an order of magnitude lower than the bandwidth of PLL 402. In a typical implementation the bandwidth of PLL 701 is less than a few kHz, e.g., in the tens or hundreds of Hz.

Thus, a nested PLL architecture has been described that can be advantageously used for various clock products. While embodiments described have two or three loops, the number of loops may be more than three. In addition, while the third loop had a recovered clock as an input, other embodiments may have other types of clock signals as the reference clock signal for the third (or additional loops). The description of the invention set forth herein is illustrative and is not intended to limit the scope of the invention as set forth in the following claims. Variations and modifications of the embodiments disclosed herein, may be made based on the description set forth herein, without departing from the scope of the invention as set forth in the following claims.

1.-20. (canceled)

21. A clock circuit comprising:
first and second phase locked loops nested together, each including a phase frequency detector configured to supply an error signal, a loop filter configured to output a loop filter output signal based on the error signal, and a feedback divider configured to divide a feedback signal;
an LC oscillator connected to the loop filter output signal of the first phase locked loop to generate the feedback signal;
an acoustic wave resonator configured to supply a resonator signal to the first phase locked loop;
a crystal oscillator configured to supply a crystal oscillator signal to the second phase locked loop; and
a divider control circuit of the second phase locked loop to control the feedback divider of the first phase locked loop based on the loop filter output signal of the second phase locked loop and the divided feedback signal of the first phase locked loop.

22. The clock circuit of claim 21 wherein the acoustic wave resonator is a surface acoustic wave resonator.

23. The clock circuit of claim 21 wherein the acoustic wave resonator is a bulk acoustic wave resonator.

24. The clock circuit of claim 21 wherein an update rate of the first phase locked loop is at least an order of magnitude greater than a frequency of the crystal oscillator.

25. The clock circuit of claim 24 wherein the update rate of the first phase locked loop is between 100 MHZ and 800 MHz.

26. The clock circuit of claim 24 wherein a first bandwidth of the first phase locked loop is at least an order of magnitude higher than a second bandwidth of the second phase locked loop.

27. The clock circuit of claim 26 wherein a first bandwidth of the first phase locked loop is between 1 MHz and 10 MHz and the second bandwidth of the second phase locked loop is between 10 kHz and 500 kHz.

28. The clock circuit of claim 21 further comprising a third phase locked loop nested together with the first and second phase locked loops and configured to receive a recovered clock signal and supply a third error signal indicative of a difference between the recovered clock signal and a third feedback signal, the third phase locked loop including a second divider control circuit coupled to a loop filter output signal of the third phase locked loop to control the feedback divider of the second phase locked loop.

29. The clock circuit of claim 28 wherein a third bandwidth of the third phase locked loop is less than 2 kHz.

30. The clock circuit of claim 28 wherein the divider control circuits of the second phase locked loop and the third phase locked loop respectively include first and second delta sigma modulators.

31. The clock circuit of claim 21 further comprising an input divider configured to receive the resonator signal of the acoustic wave resonator, divide the resonator signal, and supply the divided resonator signal to the phase frequency detector of the first phase locked loop.

32. The clock circuit of claim 21 further comprising an analog to digital converter to receive a control voltage signal and supply a digital control signal corresponding to the control voltage signal, a delta sigma modulator coupled to the digital control signal, the delta sigma modulator to control a divide value of the feedback divider of the second phase locked loop.

33. A method of operating a clock circuit, the method comprising:
at a phase frequency detector of a first phase locked loop, receiving a first reference clock signal based on a resonator signal output by an acoustic wave resonator;
generating a feedback signal based on an LC oscillator signal and a first loop filter output signal generated by a loop filter connected to the first phase frequency detector and on;
at a phase frequency detector of a second phase locked loop nested with the first phase locked loop, receiving a second reference clock signal based on a crystal oscillator signal;
at a divider control circuit of the second phase locked loop, outputting a control signal to a feedback divider of the first phase locked loop based on a loop filter output signal of the second phase locked loop and a divided feedback signal of the first phase locked loop.

34. The method of claim 33 further comprising updating the first phase locked loop at a rate that is at least an order of magnitude greater than a frequency of the crystal oscillator.

35. The method of claim 34 wherein an update rate of the first phase locked loop is greater than or equal to 100 MHZ and less than or equal to 800 MHz

36. The method of claim 34 further comprising operating the first phase locked loop with a first bandwidth, and operating the second phase locked loop with a second bandwidth, the first bandwidth being at least an order of magnitude higher than the second bandwidth.

37. The method of claim 33 further comprising:
receiving a control voltage signal at an analog to digital converter;
supplying a digital control signal corresponding to the control voltage signal to a delta sigma modulator; and
controlling a divider value of a feedback divider of the second phase locked loop using the second delta sigma modulator.

38. The method as recited in claim 33 further comprising dividing the resonator signal to generate a reference clock signal provided to the phase frequency detector of the first phase locked loop, a frequency of the reference clock signal corresponding to an update rate of the first phase locked loop.

39. The method of claim 33 wherein the acoustic wave resonator is a surface acoustic wave resonator or bulk acoustic wave resonator.

40. A clock circuit comprising:
a plurality of nested phase locked loops;
a bulk acoustic wave or surface acoustic wave resonator coupled to a first phase locked loop of the plurality of nested phase locked loops;
a crystal oscillator coupled to a second phase locked loop of the plurality of nested phase locked loops;
a first feedback divider of the first phase locked loop and a second feedback divider of the second phase locked loop coupled to an LC oscillator of the first phase locked loop; and
a first delta sigma modulator coupled to a loop filter of the second phase locked loop to control the first feedback divider, an update rate of the first phase locked loop being at least an order of magnitude greater than a frequency of the crystal oscillator.

41. The clock circuit of claim 41 further comprising:
an analog to digital converter to receive a voltage control signal and supply a digital control signal corresponding to the control voltage signal; and
a second delta sigma modulator coupled to the digital control signal, the second delta sigma modulator configured to control a second feedback divider of the second phase locked loop.
